(19) United States
(12) Patent Application Publication
(10) Pub. No.: US 2012/0024340 A1
(43) Pub. Date: Feb. 2, 2012

(54) Solar Cells With Localized Silicon/Metal Contact For Hot Spot Mitigation and Methods of Manufacture

(75) Inventor: Chris Eberspacher, Palo Alto, CA (US)

(73) Assignee: Applied Materials, Inc., Santa Clara, CA (US)

(21) Appl. No.: 13/191,186

(22) Filed: Jul. 26, 2011

Related U.S. Application Data
(60) Provisional application No. 61/367,912, filed on Jul. 27, 2010.

(51) Int. Cl. H01L 31/042; H01L 31/18; H01L 31/0224

(52) U.S. Cl. 136/244; 136/256; 438/72; 257/E31.127

(57) ABSTRACT

Embodiments of the invention are directed to photovoltaic cells, modules and methods of making the same. The photovoltaic devices comprise a superstrate, a front contact layer on the superstrate, a photoabsorber layer on the front contact, a patterned discontinuous conductive layer on the photoabsorber layer, a back contact layer in contact with the photoabsorber layer and the patterned discontinuous conductive layer and a reflective layer on the back contact layer.

### CROSS-REFERENCE TO RELATED APPLICATIONS

This application claims priority under 35 U.S.C. §119(e) to U.S. Provisional Application No. 61/367,912, filed Jul. 27, 2010.

### BACKGROUND

Embodiments of the present invention generally relate to photovoltaic modules and methods of making photovoltaic modules. Specific embodiments pertain to photovoltaic modules and photovoltaic cells incorporating technology to mitigate hot spot damage and methods of making the same.

Thin film solar modules, also called photovoltaic modules, are made up of a plurality of individual thin film solar cells, or photovoltaic cells, connected in series. Photovoltaic modules installed in the field can experience localized shadowing due to, for example, shading by nearby objects (e.g., light poles), by adjacent module strings (e.g., late in the day when the sun angle is low such that one row of modules shades another) as well as by other means.

To assure module durability in the event of such shading, modules must pass a “hot spot” test in which a multi-cell module is electrically short-circuited in full sunlight while a subset of cells is shadowed. In this hot spot test, the power photogenerated in the illuminated cells is dissipated in the shadowed cells, heating the shadowed cells. Should the temperature of the shadowed cells be sufficient for the module to fail (e.g., glass breakage, encapsulation melt, junction box detachment, fire, etc.) then the module is said to fail the hot spot test.

FIG. 1 shows cross-sections of common process steps in the manufacture of thin-film photovoltaic modules. A substrate 10 is coated with a layer of a transparent conductive oxide (TCO) 20 material. One or more silicon layers 30 are deposited over the TCO layer 20. These silicon layer(s) 30 is/are the primary light absorbing structure in the photovoltaic module. A metal layer 40 is deposited over the silicon layer(s) 30. Photovoltaic modules of this type demonstrate good reverse current flow due to the silicon layer 30 to metal layer 40 contact, but poor back contact optical reflection.

FIG. 2 shows cross-sections of photovoltaic module processing steps according to other manufacturing processes. In these processes, the substrate 10 is coated with a TCO layer 20 and silicon layers 30. A second TCO layer 50 is deposited over the silicon layers 30 and a metal layer 40 is deposited over the second TCO layer 50. Photovoltaic modules of this variety demonstrate good back contact optical reflection due to the silicon layer 30—second TCO layer 50—metal layer 40 contact. These devices show poor reverse current flow, and therefore, hot spot problems can occur.

Therefore, there is a need in the art for photovoltaic modules and methods of making photovoltaic modules that have good optical reflection and reverse current flow and can more likely pass a hot spot test and remain stable under conditions of use.

### SUMMARY OF THE INVENTION

One or more embodiments of the invention are directed to photovoltaic cells comprising a superstrate with a front contact layer on the superstrate and a photoabsorber layer on the front contact layer. The photoabsorber layer comprises one or more of an n-type layer, a p-type layer and an intrinsic layer. A patterned discontinuous conductive layer is on the photoabsorber layer. A back contact layer is in contact with the photoabsorber layer and the patterned discontinuous conductive layer. A reflective layer on the back contact layer is on the back contact layer. The reflective back contact layer is adapted to reflect incident light not absorbed by the photoabsorber layer.

Additional embodiments of the invention are directed to photovoltaic modules comprising a plurality of the photovoltaic cells as described connected in series.

Further embodiments of the invention are directed to methods of manufacturing a photovoltaic cell. A front contact layer is deposited onto a superstrate. A photoabsorber layer is deposited onto the front contact. The photoabsorber layer is adapted to convert light energy into electrical current. The photoabsorber layer includes one or more sublayers selected from the group consisting of p-type, n-type and instrinsic sublayers. A patterned discontinuous conductive layer is deposited on the photoabsorber layer. A back contact layer is deposited onto the patterned discontinuous conductive layer. A reflective layer is deposited on the back contact layer.

In some embodiments, the patterned discontinuous conductive layer comprises a metal. In specific embodiments, the metal is selected from the group consisting of silver, copper, aluminum, indium, tin, nickel, molybdenum, chromium, tantalum, titanium and combinations thereof.

In various embodiments, the patterned discontinuous conductive layer has a pattern selected from the group consisting of random distributions, grid-like distribution, one-dimensional grid, equally spaced dots and combinations thereof.

In specific embodiments, the patterned discontinuous conductive layer covers up to about 10% of the photoabsorber layer. The patterned discontinuous conductive layer of some embodiments extends through the back contact layer and contacts the reflective layer.

According to various embodiments, one or more of the front contact layer and the back contact layer comprises a transparent conductive oxide. In detailed embodiments, the transparent conductive oxide is aluminum doped zinc oxide. In specific embodiments, the photoabsorber layer comprises silicon.

Some detailed embodiments have the reflective layer comprising one or more of a paint layer, a polymer layer impregnated with a white pigment, and a metal selected from the group consisting of silver, copper and combinations thereof.

Some embodiments comprise laser scribing the front contact layer, the photoabsorber layer and the back contact layer to create a plurality of individual photovoltaic cells connected in series.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a cross-sectional view of a process for making photovoltaic modules;

FIG. 2 shows a cross-sectional view of a process for making photovoltaic modules;

FIG. 3A shows a process for making photovoltaic modules according to one or more embodiments of the invention;

FIG. 3B show a cross-sectional view of a process for making photovoltaic modules according to one or more embodiments of the invention;

FIG. 4A is a side cross-sectional view of a thin film photovoltaic modules according to one or more embodiment of the invention;

FIG. 4B is a side cross-sectional view of a thin film photovoltaic modules according to one or more embodiment of the invention;

FIG. 5 is a plan view of a composite photovoltaic module according to one or more embodiment of the invention;

FIG. 6 is a side cross-sectional view along Section 6-6 of FIG. 5;

FIG. 7 is a side cross-sectional view along Section 7-7 of FIG. 5;

FIG. 8 shows a cross-sectional view of a process for making thin film photovoltaic modules according to one or more embodiment of the invention;

FIG. 9 shows a cross-sectional view of a thin film photovoltaic module according to one or more embodiment of the invention; and

FIG. 10 shows various patterns for localized metal according to one or more embodiments of the invention.

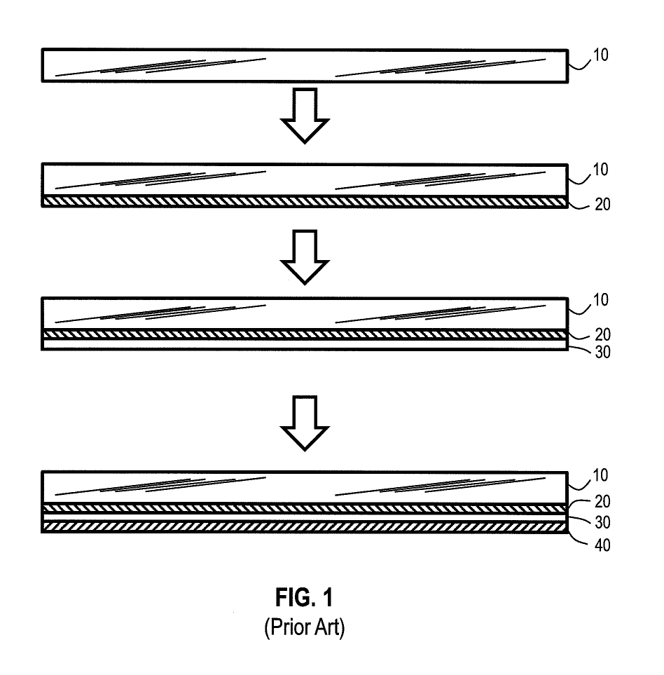

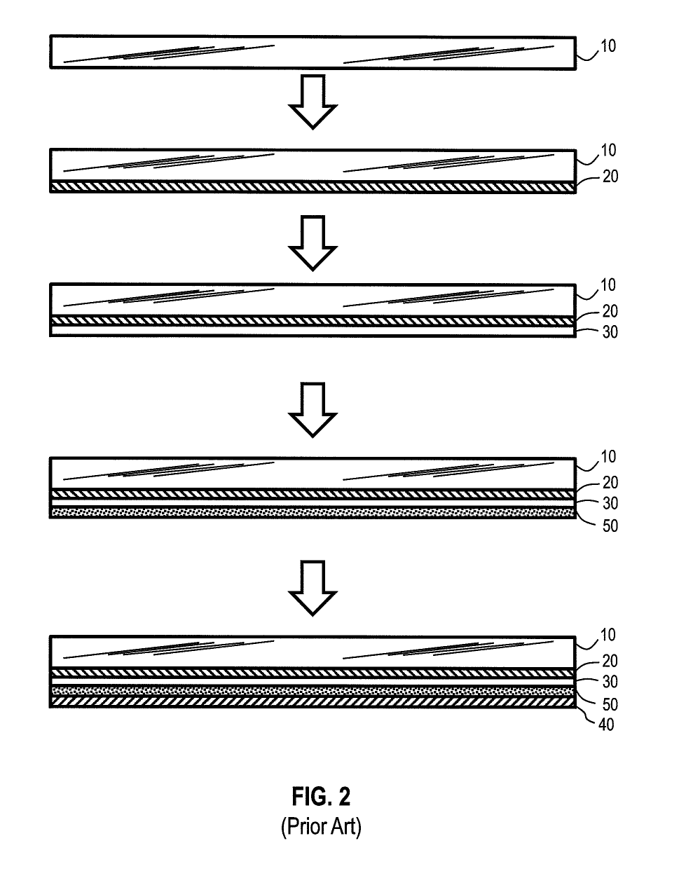

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, the singular forms “a”, “an” and “the” include plural referents unless the context clearly indicates otherwise. For example, reference to a “cell” may also refer to more than one cell, and the like.

The term “photovoltaic cell” is used to describe an individual stack of layers suitable for converting light into electricity. The term “solar cell” and the like are used interchangeably with “photovoltaic cell.” The term “photovoltaic module” is used to describe a plurality of photovoltaic cells connected in series. The term “solar module” and the like are used interchangeably with “photovoltaic module.”

According to embodiments of the invention, the likelihood of a thin-film photovoltaic module passing the hot spot test is improved by providing a means for a direct silicon to metal back contact in localized areas such that the reverse current conductance is increased so that the maximum temperature of a shaded cell during the hot spot test is lower.

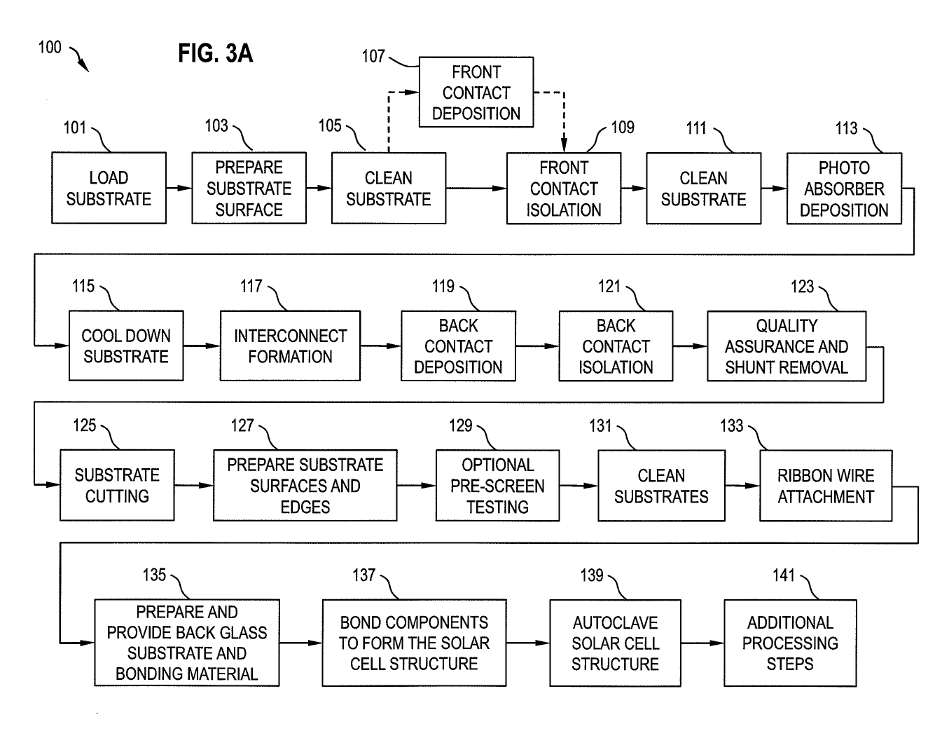

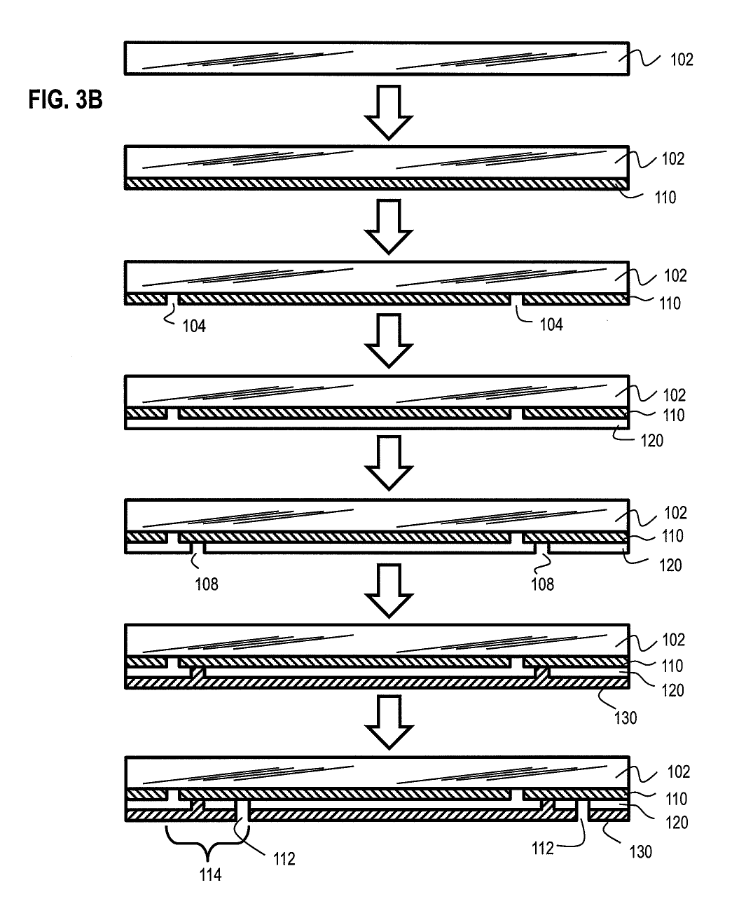

FIGS. 3A and 3B illustrate a typical process sequence 100 used in the manufacture of solar cells. It is to be understood that the invention is not limited to the process sequence illustrated and described below. Other manufacturing processes can be employed without deviating from the spirit and scope of the invention.

The process sequence 100 generally starts at step 101 in which a superstrate 102 is loaded into a loading module. The superstrate 102 may be received in a “raw” state where the edges, overall size, and/or cleanliness of the substrates are not well controlled. Receiving “raw” substrates reduces the cost to prepare and store substrates prior to forming a solar module and thus reduces the solar cell module cost, facilities costs, and production costs of the finally formed solar cell module. However, typically, it is advantageous to receive “raw” substrates that have a transparent conducting oxide (TCO) layer already deposited on a surface of the superstrate 102 before it is received into the system in step 101. If a front contact layer 110, such as TCO layer, is not deposited on the surface of the “raw” superstrate 102 then a front contact deposition step (step 107), which is discussed below, needs to be performed on a surface of the superstrate 102.

The superstrate 102 is often made of glass, but other materials including, but not limited to, polymeric materials can be employed. Additionally, the superstrate 102 can be made of a rigid or flexible material. An exemplary thickness for a glass sheet is about 3 mm. In the art, this superstrate 102 may be referred to as a substrate because a plurality of material layers are deposited onto the superstrate 102.

In step 103, the surfaces of the superstrate 102 are prepared to prevent yield issues later in the process. The superstrate 102 may be inserted into a front end substrate seaming module that is used to prepare the edges of the superstrate 102 to reduce the likelihood of damage, such as chipping or particle generation from occurring during the subsequent processes. Damage to the superstrate 102 can affect module yield and the cost to produce a usable photovoltaic module.

Next, the superstrate 102 is cleaned (step 105) to remove any contaminants found on the surface. Common contaminants may include materials deposited on the superstrate 102 during the substrate forming process (e.g., glass manufacturing process) and/or during shipping or storing of the superstrate 102. Typically, cleaning uses wet chemical scrubbing and rinsing steps to remove any undesirable contaminants, but other cleaning processes can be employed.

If the superstrate 102 loaded in step 101 does not have a front contact layer 110 on the surface, a front contact layer 110 is deposited in step 107. The front contact layer 110 is often a transparent conductive oxide (TCO) layer, and may be referred to as a “first TCO layer” throughout this specification. The superstrate 102 may be transported to a front end processing module in which a front contact formation process, step 107, is performed on the superstrate 102. In step 107, the one or more substrate front contact formation steps may include one or more of preparation, etching, and/or material deposition steps to form the front contact regions on a bare superstrate 102. Step 107 may comprise one or more physical vapor deposition (PVD) steps or chemical vapor deposition (CVD) steps that are used to form the front contact region on a surface of the superstrate 102.

Suitable materials for the front contact layer 110 include, but are not limited to, aluminum-doped zinc oxide (AZO), indium tin oxide (ITO), indium molybdenum oxide (IMO), indium zinc oxide (IZO) and tantalum oxide. In some embodiments, the front contact region may contain a transparent conducting oxide (TCO) layer 110 that contains a metal element selected from a group consisting of zinc (Zn), aluminum (Al), indium (In), tantalum (Ta) molybdenum (Mo) and tin (Sn). In a specific embodiment, zinc oxide (ZnO) is used to form at least a portion of the front contact layer 110.

In step 109, separate cells are electrically isolated from one another via scribing processes. Contamination particles on the front contact layer 110 surface and/or on the bare glass superstrate 102 surface can interfere with the scribing procedure. In laser scribing, for example, if the laser beam runs across a particle, it may be unable to scribe a continuous line, resulting in a short circuit between cells. In addition, any particulate debris present in the scribed pattern and/or on the front contact layer 110 of the cells after scribing can cause shunting and non-uniformities between layers.

The device superstrate 102 is transported to the scribe module in which step 109, or a front contact isolation step, is performed on the device superstrate 102 to electrically isolate different regions of the device superstrate 102 surface from each other. In step 109, material is removed from the device superstrate 102 surface by use of a material removal step, such as a laser ablation process. The success criteria for step 109 are to achieve good cell-to-cell and cell-to-edge isolation while minimizing the scribe area. The front contact isolation step 109 uses a laser scribing process, often referred to as P1, which scribes strips 104 through the entire thickness of the front contact layer 110. The scribed strips are usually 5-10 mm apart, but larger and smaller distances can be used.

Next, the device superstrate 102 is transported to a cleaning module in which step 111, a pre-deposition substrate cleaning step, is performed on the device superstrate 102 to remove any contaminants found on the surface of the device superstrate 102 after performing the cell isolation step 109. Typically, cleaning uses wet chemical scrubbing and rinsing steps to remove any undesirable contaminants found on the device superstrate 102 surface after performing the cell isolation step.

Next, the device superstrate 102 is transported to a processing module in which step 113, which comprises one or more photoabsorber layer 120 deposition steps, is performed on the device superstrate 102. In step 113, the one or more photoabsorber layer 120 deposition steps may include one or more of preparation, etching, and/or material deposition steps that are used to form the various regions of the solar cell device. Step 113 generally comprises a series of sub-processing steps that are used to form one or more p-i-n junctions. In some embodiments, the one or more p-i-n junctions comprise amorphous silicon and/or microcrystalline silicon materials. Step 113 can include multiple p-layers, i-layers and n-layers, as in the case of multi-junction photovoltaic modules. In specific embodiments, the photoabsorber layer 120 comprises one or more of an n-type layer, a p-type layer and an intrinsic layer. In specific embodiments, the photoabsrober layer 120 comprises silicon.

A cool down step, or step 115, may be performed after step 113. The cool down step is generally used to stabilize the temperature of the device superstrate 102 to assure that the processing conditions seen by each device superstrate 102 in the subsequent processing steps are repeatable. Generally, the temperature of the device superstrate 102 exiting a processing module can vary by many degrees and exceed a temperature of 50° C., which can cause variability in the subsequent processing steps and solar cell performance.

Next, the device superstrate 102 is transported to a scribe module in which step 117, or the interconnect formation step, is performed on the device superstrate 102 to electrically isolate various regions of the device superstrate 102 surface from each other. In step 117, material is removed from the device superstrate 102 surface by use of a material removal step, such as a laser ablation process. This second laser scribing step, often referred to as P2, completely cuts scribes 108 through the photoabsorber layer 120.

Next, the device superstrate 102 may be subjected to one or more substrate back contact formation steps, or step 119. In step 119, a back contact layer 130, also referred to as a second TCO layer, is formed on the photoabsorber layer 120. The one or more back contact layer 130 formation steps may include one or more of preparation, etching, and/or material deposition steps that are used to form the back contact regions of the solar module. Step 119 generally comprises one or more PVD steps or CVD steps that are used to form the back contact layer 130 on the surface of the photoabsorber layer 120. In detailed embodiments, the one or more PVD steps are used to form a back contact region that contains a metal layer selected from a group consisting of zinc (Zn), tin (Sn), aluminum (Al), copper (Cu), silver (Ag), nickel (Ni), vanadium (V), molybdenum (Mo), and conductive carbon.

According to one or more embodiments, the average temperature of shadowed reverse-biased photovoltaic cells is reduced in a so-called hot spot test by forming localized areas where the metal of a typical transparent conductor/metal back contact directly contacts the silicon, forming a silicon/metal interface that has been shown to have higher reverse-bias conductance while maintaining high forward-bias rectification. A silicon/back contact structure is formed where the major area of the silicon/back contact is a high-reflectance silicon/oxide/metal structure conductive to maximizing photocurrent density and the minor area is a lower-reflectance higher-reverse-conductance silicon/metal structure conducive to conducting reverse current with minimal average cell heating.

Without being bound by any particular theory of operation, it is believed that forming a distributed (e.g. a high area density of small areas) high-reverse-bias conductance the reverse current dissipated in a shadowed cell is dissipated in said distributed areas of high-reverse-bias conductance so that the dissipated power is laterally distributed across the shadowed cell thereby better distributing the heat generated by the dissipation, thereby lowering the average cell temperature relative to the case where a low-reverse-bias conductance silicon/oxide/metal contact causes reverse-bias current to preferentially flow only in a few small areas (e.g. where local defects cause higher-than-average reverse-bias conductance) so that local maximum temperatures at or near those local defects is much higher than the average maximum temperatures in cells with higher, distributed reverse-bias conductance.

In detailed embodiments, the majority of the silicon may be in contact with a high-reflectance silicon/oxide/metal stack that maximizes photocurrent density while a minority of the silicon may be contacted with a high-conductance silicon/metal stack that minimizes average heating during reverse-bias current flow (e.g., while shadowed in a hot spot test). For example, it may be possible to cover 90+% of the silicon with oxide/metal while covering <10% of the silicon with metal to retain near-maximum photocurrent while assuring hot spot protection.

Specific embodiments are directed to structures and methods in which a distributed silicon/metal contact is formed by depositing metal in localized areas prior to depositing a standard oxide/metal back contact over the total area. A method for forming localized silicon/metal contacts is to spray a metal-containing ink or dilute paste—such as silver-containing pastes as are often used for forming c-silicon solar cell grid contacts. In specific embodiments, a mid-frequency (e.g. 10-20 kHz) ultrasonic spray nozzle with a solvent-diluted silver ink is distributed over the surface so that localized silicon/silver splotches occur that would serve as high reverse-bias conductance areas.

Some embodiments use other methods to form local silicon/metal contacts, such as shadowing of certain areas during oxide deposition, e.g. close-to-substrate wire shadow masks under an oxide sputtering target so that stripes of silicon are uncovered by the oxide—e.g. ZnO:Al—such that subsequent all-area coverage by Al or Ag creates a majority area of high-photocurrent silicon/oxide/metal and a minority area (e.g. stripes as defined by the above mentioned wire masks) of high-conductance silicon/metal.

The localized areas of silicon/metal can be in many patterns. Suitable patterns include, but are not limited to, stripes, dots, webs, geometric patterns, and random patterns. Additionally, the coverage ratios can be varied. Suitable coverage ratios include, but are not limited to, 10:1 silicon/oxide/metal:silicon/metal coverage.

In some detailed embodiments, the localized areas of silicon/metal can be formed by patterning the oxide. The oxide can be patterned by, for example, depositing metal first in local areas (e.g. by depositing metal in localized areas prior to depositing any oxide) by masking the silicon in certain areas during oxide deposition. Then removing oxide from the silicon in certain areas (e.g. by mechanical, chemical or ablative means), and/or by diffusing metal through the oxide in certain areas.

A contact according to one or more embodiments of the present invention might comprise a single metal used for both the localized and distributed contacts. Additionally, the contact might comprise multiple metals for different purposes. Suitable examples include, but are not limited to, depositing Ag in localized areas to form a high-conductance contact and depositing ZnO:Al in most areas to form a high-reflectance, low-cost contact.

An example of one or more embodiments of the inventive method is to dilute Cabot Ag ink in a suitable diluent solvent. The dilute ink can then be sprayed (spritzed) onto a bare silicon plate after P2 laser patterning and prior to ZnO/Ag. The dilute ink can be dried and cured in any in-line drying oven to form local Si/Ag high-conductance contact areas. Then, ZnO/Ag can be deposited by, for example, physical vapor deposition to form a distributed high-reflectance contact.

Next, the device superstrate 102 is transported to a scribe module in which step 121, or a back contact isolation step, is performed on the device superstrate 102 to electrically isolate the plurality of solar cells contained on the substrate surface from each other. In step 121, material is removed from the substrate surface by use of a material removal step, such as a laser ablation process. This third scribing process, called P3, is used to scribe strips 112 through the back contact layer 130 and the photoabsorber layer 120. The area between, and including, the P1 and P3 scribes results in a dead zone 114 which decreases the overall efficiency of the cell. The dead zone is typically in the range of about 100 μm to about 500 μm, depending on the accuracy of the lasers and optics employed in the scribing processes.

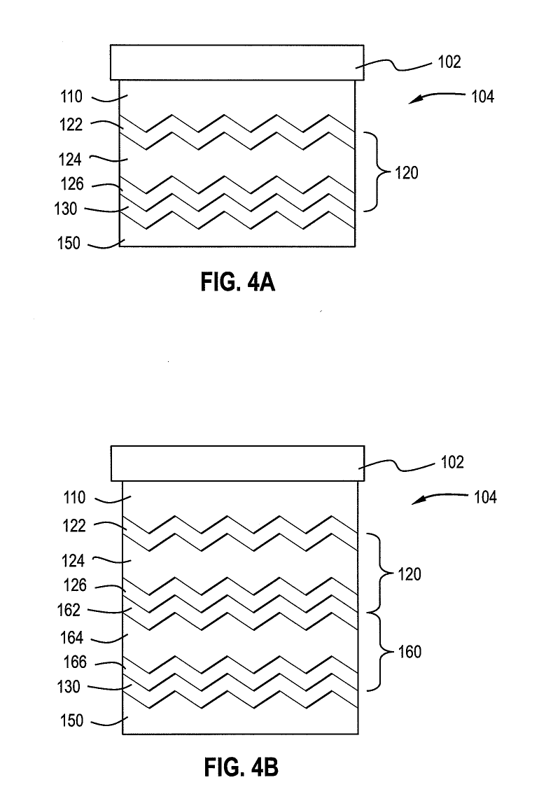

FIG. 4A shows a single junction amorphous silicon photovoltaic cell 104. The photovoltaic cell 104 shown comprises a superstrate 102 such as a glass substrate, polymer substrate, metal substrate, or other suitable substrate, with thin films formed thereon. In a specific embodiment, the superstrate 102 is a glass substrate that is about 2200 mm×2600 mm×3 mm in size. The solar cell 104 further comprises a first transparent conducting oxide (TCO) layer 110 (e.g., zinc oxide (ZnO), tin oxide (SnO)) formed over the superstrate 102, a first photoabsorber layer 120, comprising a p-i-n junction, formed over the front contact layer 110. A back contact layer 130 is formed over the first photoabsorber layer 120, and a reflective layer 150, or stack of layers, is formed over the back contact layer 130. To improve light absorption by enhancing light trapping, the superstrate 102 and/or one or more of the thin films formed thereover may be optionally textured by wet, plasma, ion, and/or mechanical processes. For example, in the embodiment shown in FIG. 4A, the front contact layer 110 is textured, and the subsequent thin films deposited thereover generally follow the topography of the surface below it.

In the detailed embodiment shown in FIG. 4A, the first photoabsorber layer 120 comprises a p-type amorphous silicon layer 122, an intrinsic type amorphous silicon layer 124 formed over the p-type amorphous silicon layer 122, and an n-type microcrystalline silicon layer 126 formed over the intrinsic type amorphous silicon layer 124. The p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type microcrystalline silicon layer 126 may be formed to a thickness between about 100 Å and about 400 Å. The back contact layer 130 is deposited over the photoabsorber layer 120 and is often a second transparent conductive oxide layer. A reflective layer 150 is deposited over the back contact layer 130. The reflective layer 150 is often considered to be a sublayer in a back contact stack, which can also include the back contact layer 130. The reflective layer 150 may include, but is not limited to, a material selected from the group consisting of Al, Ag, Ti, Cr, Au, Cu, Pt, Ni, Mo, conductive carbon, alloys thereof, and combinations thereof. In detailed embodiments, the reflective layer 150 comprises one or more of a paint layer, a polymer layer impregnated with a white pigment, and a metal selected from the group consisting of silver, copper and combinations thereof.

FIG. 4B is a schematic diagram of an embodiment of a solar cell 104, which is a multi-junction solar cell. The solar cell 104 of FIG. 4B comprises a superstrate 102, such as a glass substrate, polymer substrate, metal substrate, or other suitable substrate, with thin films formed thereover. The solar cell 104 may further comprise a first transparent conducting oxide (TCO) layer 110 formed over the superstrate 102, a first photoabsorber layer 120 formed over the front contact layer 110, a second photoabsorber layer 160 formed over the first photoabsorber layer 120, a back contact layer 130 formed over the second photoabsorber layer 160, and a reflective layer 150 formed over the back contact layer 130.

In the embodiment shown in FIG. 4B, the front contact layer 110 is textured, and the subsequent thin films deposited thereover generally follow the topography of the surface below it. The first photoabsorber layer 120 may comprise a p-type amorphous silicon layer 122, an intrinsic type amorphous silicon layer 124 formed over the p-type amorphous silicon layer 122, and an n-type microcrystalline silicon layer 126 formed over the intrinsic type amorphous silicon layer 124. In one example, the p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type microcrystalline silicon layer 126 may be formed to a thickness between about 100 Å and about 400 Å.

The second photoabsorber layer 160 may comprise a p-type microcrystalline silicon layer 162, an intrinsic type microcrystalline silicon layer 164 formed over the p-type microcrystalline silicon layer 162, and an n-type amorphous silicon layer 166 formed over the intrinsic type microcrystalline silicon layer 164. In one example, the p-type microcrystalline silicon layer 162 may be formed to a thickness between about 100 Å and about 400 Å, the intrinsic type microcrystalline silicon layer 164 may be formed to a thickness between about 10,000 Å and about 30,000 Å, and the n-type amorphous silicon layer 166 may be formed to a thickness between about 100 Å and about 500 Å. The reflective layer 150 may include, but is not limited to a material selected from the group consisting of Al, Ag, Ti, Cr, Au, Cu, Pt, Ni, Mo, conductive carbon, alloys thereof, and combinations thereof.

Next, the device superstrate 102 is transported to a quality assurance module in which step 123, or quality assurance and/or shunt removal steps, are performed on the device superstrate 102 to assure that the devices formed on the substrate surface meet a desired quality standard and in some cases correct defects in the formed device. In step 123, a probing device is used to measure the quality and material properties of the formed photovoltaic module by use of one or more substrate contacting probes.

Next, the device superstrate 102 is optionally transported to a substrate sectioning module in which a substrate sectioning step 125 is used to cut the device superstrate 102 into a plurality of smaller devices to form a plurality of smaller photovoltaic modules. Instead of directly cutting the device superstrate 102 into smaller sections, the substrate sectioning step 125 may form a series of scored lines. The device superstrate 102 may then be broken along the scored lines to produce the desired size and number of sections needed for the completion of the solar cell devices.

The superstrate 102 is next transported to a seamer/edge deletion module in which a substrate surface and edge preparation step 127 is used to prepare various surfaces of the device superstrate 102 to prevent yield issues later on in the process. Damage to the device superstrate 102 edge can affect the device yield and the cost to produce a usable solar cell device. The seamer/edge deletion module may be used to remove deposited material from the edge of the device superstrate 102 (e.g., 10 mm) to provide a region that can be used to form a reliable seal between the device superstrate 102 and the backside glass (i.e., steps 137 and 139 discussed below). Material removal from the edge of the device superstrate 102 may also be useful to prevent electrical shorts in the final formed solar cell.

The device superstrate 102 is then transported to a pre-screen module in which optional pre-screen steps 129 are performed on the device superstrate 102 to assure that the devices formed on the substrate surface meet a desired quality standard. In step 129, a light emitting source and probing device may be used to measure the output of the formed solar cell device by use of one or more substrate contacting probes. If the module detects a defect in the formed device it can take corrective actions or the solar cell can be scrapped.

Next the device superstrate 102 is transported to a cleaning module in which step 131, or a pre-lamination substrate cleaning step, is performed on the device superstrate 102 to remove any contaminants found on the surface of the superstrate 102 after performing the preceding steps. Typically, the cleaning uses wet chemical scrubbing and rinsing steps to remove any undesirable contaminants found on the substrate surface after performing the cell isolation step.

The superstrate 102 may then be transported to a bonding wire attach module in which a bonding (or ribbon) wire attach step 133 is performed on the superstrate 102. Step 133 is used to attach the various wires/leads required to connect various external electrical components to the formed solar cell module. The bonding wire attach module may be an automated wire bonding tool that reliably and quickly forms the numerous interconnects required to produce large solar cells.

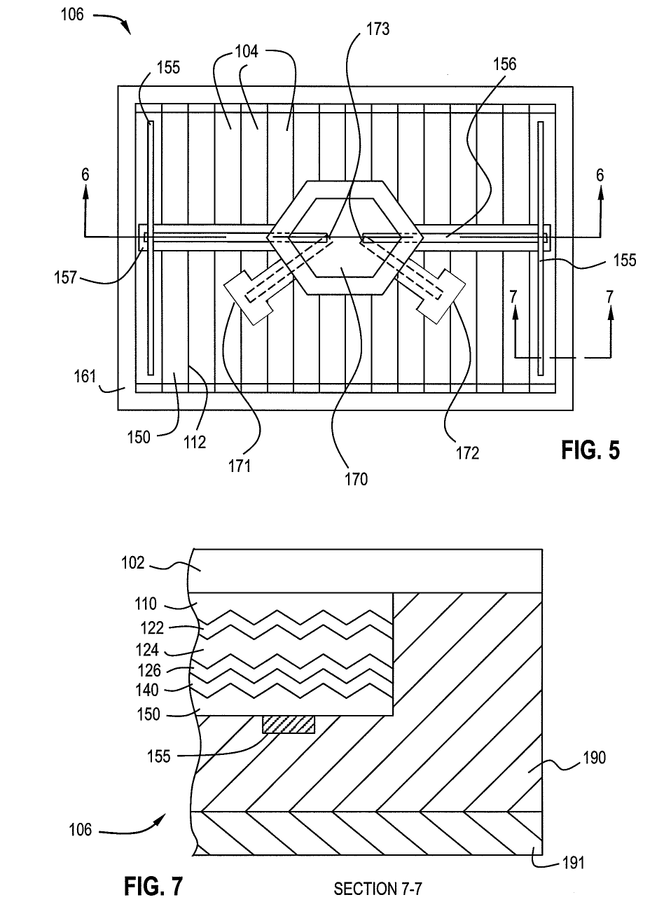

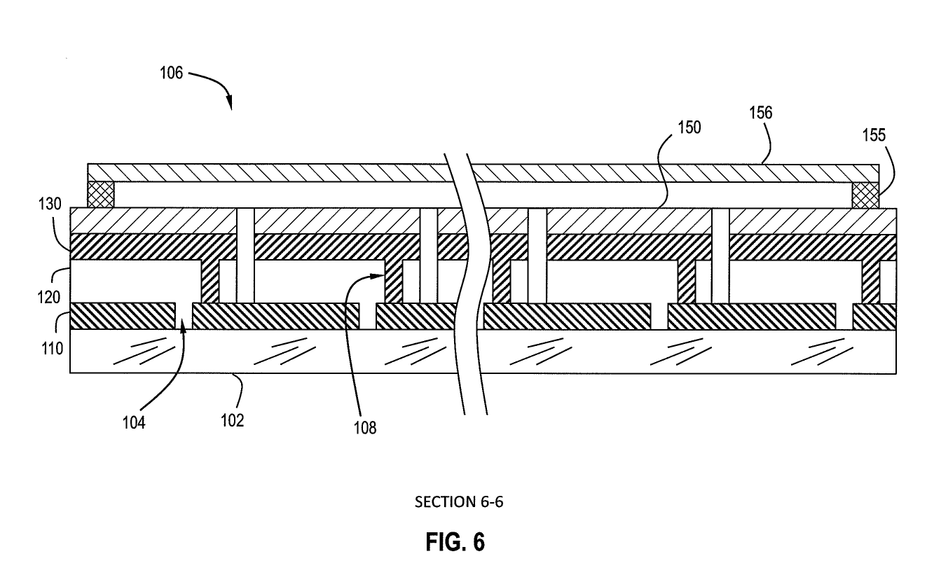

FIG. 5 shows a plan view that schematically illustrates an example of the rear surface of a formed solar cell module 106 produced by the previously described procedure. FIG. 6 is a side cross-sectional view of the solar cell module 106 illustrated in FIG. 5 (see section 6-6). FIG. 7 is a side cross-sectional view of a portion of the solar cell module 106 illustrated in FIG. 5 (see section 7-7). While FIG. 7 illustrates the cross-section of a single junction cell similar to the configuration described in FIG. 4A, this is not intended to be limiting as to the scope of the invention described herein.

The solar cell module 106 shown in FIG. 5-7 contains a superstrate 102, the solar cell device elements (e.g., reference numerals 110-150), one or more internal electrical connections (e.g., side-buss 155, cross-buss 156), a layer of bonding material 190, a back glass substrate 191, and a junction box 170. The junction box 170 generally contains two junction box terminals 171, 172 that are electrically connected to the leads 173 of the solar cell module 106 through the side-buss 155 and the cross-buss 156, which are in electrical communication with the reflective layer 150 and active regions of the solar cell module 106. An edge delete region 161 is shown around the perimeter of the photovoltaic module 106

FIG. 6 is a schematic cross-section of a solar cell module 106 illustrating various scribed regions used to form the individual cells within the solar cell module 106. As illustrated in FIG. 6, the solar cell module 106 includes a transparent superstrate 102, a front contact layer 110, a first photoabsorber layer 120, a back contact layer 130 and a reflective layer 150. Three laser scribes 104, 108, 112 produce trenches to form a high efficiency solar cell device. Although formed together on the superstrate 102, the individual cells are isolated from each other by the insulating trench (e.g., scribe 112) formed in the back contact layer 130 and reflective layer 150. In addition, a scribe 108 trench is formed in the first photoabsorber layer 120 so that the reflective layer 150 is in electrical contact with the front contact layer 110 of the adjacent cell. In one embodiment, the P1 scribe line 104 is formed by the removal of a portion of the front contact layer 110 prior to the deposition of the first photoabsorber layer 120, back contact layer 130 and reflective layer 150. Similarly, in one embodiment, the P2 scribe 108 forms a trench in the first photoabsorber layer 120 by the removal of a portion of the first photoabsorber layer 120 prior to the deposition of the back contact layer 130 and the reflective layer 150. While a single junction type solar cell is illustrated in FIG. 6 this configuration is not intended to be limiting to the scope of the invention described herein.

In some embodiments, step 133 includes a bonding wire attach module which is used to form the side-buss 155 and cross-buss 156 on the formed back contact. In this configuration, the side-buss 155 may comprise a conductive material that can be affixed, bonded, and/or fused to the reflective layer 150 to form a robust electrical contact. In one embodiment, the side-buss 155 and cross-buss 156 each comprise a metal strip, such as copper tape, a nickel coated silver ribbon, a silver coated nickel ribbon, a tin coated copper ribbon, a nickel coated copper ribbon, or other conductive material that can carry current delivered by the solar cell module 106 and that can be reliably bonded to the reflective layer 150. In a specific embodiment, the metal strip is between about 2 mm and about 10 mm wide and between about 1 mm and about 3 mm thick.

The cross-buss 156, which is shown electrically connected to the side-buss 155, can be electrically isolated from the reflective layer 150 of the solar cell module 106 by use of an insulating material 157, such as an insulating tape. The ends of each of the cross-busses 156 generally have one or more leads 162 that are used to connect the side-buss 155 and the cross-buss 156 to the electrical connections found in a junction box 170, which is used to connect the formed solar cell module 106 to other external electrical components.

As best shown in the partial cross-section view of FIG. 7, in the next steps, step 132 and 134, a bonding material 360 and “back glass” substrate 361 is provided and applied. The back glass substrate 361 is bonded onto the device superstrate 102 by use of a laminating process (step 134 discussed below). In a detailed embodiment of step 132, a polymeric material is placed between the back glass substrate 361 and the deposited layers on the device superstrate 102 to form a hermetic seal to prevent the environment from attacking the solar cell during its life.

The device superstrate 102, the back glass substrate 191, and the bonding material 190 are transported to a bonding module in which step 135 and step 139 are performed. Portions of these steps include lamination to bond the backside glass substrate 191 to the device substrate. In step 137, a bonding material 190, such as Polyvinyl Butyral (PVB) or Ethylene Vinyl Acetate (EVA), may be sandwiched between the backside glass substrate 191 and the device superstrate 102. Heat and pressure are applied to the structure to form a bonded and sealed device using various heating elements and other devices found in the bonding module. The device superstrate 102, the back glass substrate 191, and the bonding material 190 thus form a composite solar cell structure, as shown in FIG. 7 that at least partially encapsulates the active regions of the solar cell device. In some embodiments, at least one hole formed in the back glass substrate 191 remains at least partially uncovered by the bonding material 190 to allow portions of the cross-buss 156 or the side-buss 155 to remain exposed so that electrical connections can be made to these regions of the solar cell structure in future steps.

Next the composite solar cell structure is transported to an autoclave module in which step 139, or autoclave steps are performed on the composite solar cell structure to remove trapped gasses in the bonded structure and assure that a good bond is formed. In step 137, a bonded solar cell structure is inserted in the processing region of the autoclave module where heat and high pressure gases are delivered to reduce the amount of trapped gas and improve the properties of the bond between the device superstrate 102, back glass substrate 191, and bonding material 190. The processes performed in the autoclave are also useful to assure that the stress in the glass and bonding layer (e.g., PVB layer) are more controlled to prevent future failures of the hermetic seal or failure of the glass due to the stress induced during the bonding/lamination process. It may be desirable to heat the device superstrate 102, back glass substrate 191, and bonding material 190 to a temperature that causes stress relaxation in one or more of the components in the formed solar cell structure.

Additional processing steps 141 may be performed, including but not limited to device testing, additional cleaning, attaching the device to a support structure, unloading modules from processing chambers and shipping.

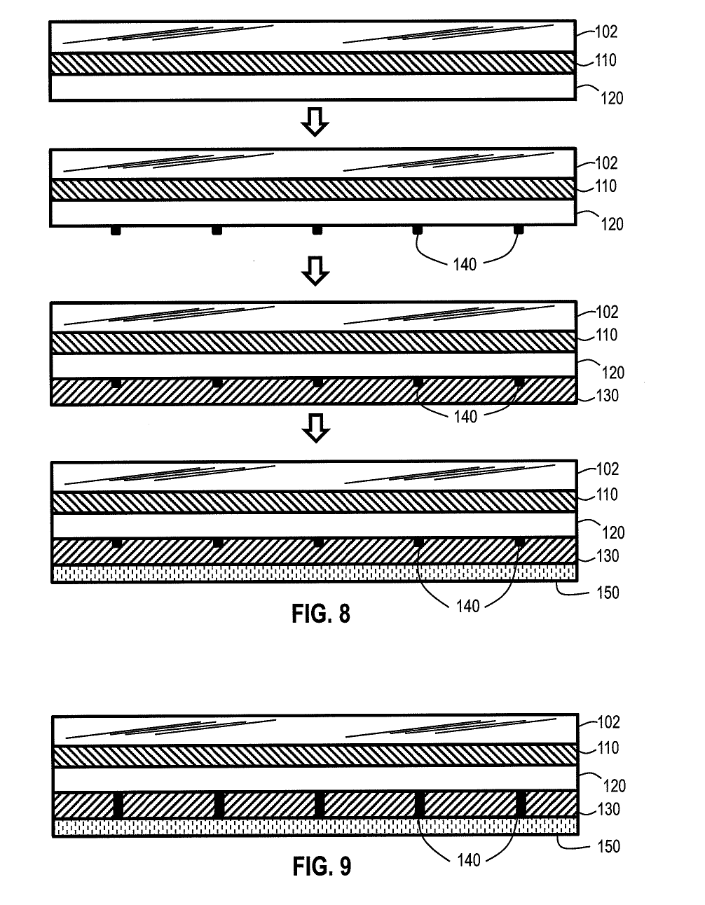

Accordingly, with reference to FIG. 8, one or more embodiments of the invention are directed to methods of manufacturing a photovoltaic cell and/or photovoltaic module. For clarity of illustration, FIG. 8 is shown without any scribe lines 104, 108, 112. A front contact layer 110 is deposited onto a superstrate 102. A photoabsorber layer 120 is deposited onto the front contact layer 110. The photoabsorber layer 120 is adapted to convert light energy into electrical current and includes one or more sublayers. In specific embodiments, the one or more sublayers are selected from the group consisting of p-type, n-type and instrinsic sublayers. A patterned discontinuous conductive layer 140 is deposited onto the photoabsorber layer 120. A back contact layer 130 is deposted onto the patterned discontinuous conductive layer 140, and a reflective layer 150 is deposited onto the back contact layer 130.

FIG. 8 shows an embodiment of the patterned discontinuous conductive layer 140 which extends from the photoabsorber layer 120 into the back contact layer 130, but does not touch the reflective layer 150. FIG. 9 shows an alternate embodiment in which the patterned discontinuous conductive layer 140 extends from the photoabsorber layer 120 through the back contact layer 130 and contacts the reflective layer 150. Some embodiments of the invention represent a combination of the embodiments shown in FIGS. 8 and 9, where a portion of the patterned discontinuous conductive layer 140 extends through the back contact layer 130 to contact the reflective layer 150, and a portion of the patterned discontinuous conductive layer 140 does not extend through the back contact layer 130.

In detailed embodiments, the patterned discontinuous conductive layer 140 comprises a metal. In specific embodiments, the metal is selected from the group consisting of silver, copper, aluminum, indium, tin, nickel, molybdenum, chromium, tantalum, titanium and combinations thereof. In various embodiments, the patterned discontinuous conductive layer 140 comprises the same material used in the reflective layer 150. In some embodiments, patterned discontinuous conductive layer 140 comprises a different material than that used in the reflective layer 150

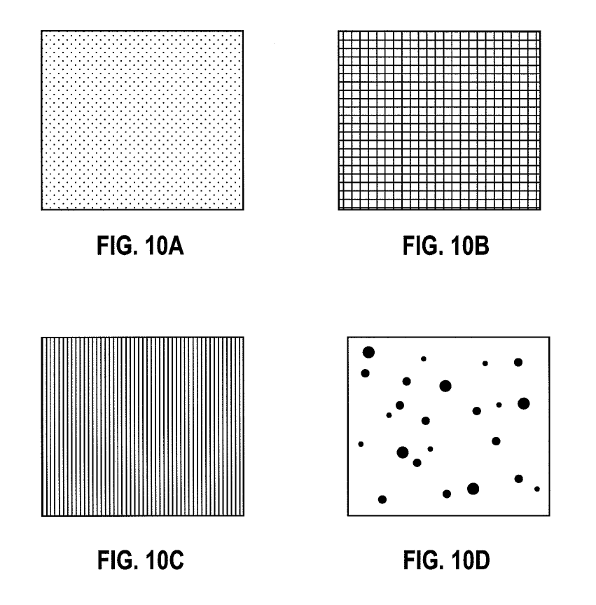

The patterned discontinuous conductive layer 140 can have a variety of patterns. FIG. 10 shows four non-limiting examples of suitable patterns. These patterns are merely illustrative and should not be taken as limiting the scope of the invention. FIG. 10A shows a pattern of separated dots or hemispheres in a predictable pattern. FIG. 10B shows a two-dimensional grid which may be useful in aiding lateral conduction across a photovoltaic module. FIG. 100 shows a one-dimensional grid which also may aid in the conductance in a particular direction with minimal coverage. FIG. 10D shows a random pattern of dots. Any of these patterns, or others, can be used and may extend through the back contact layer 130, or not. In specific embodiments, the pattern is selected from the group consisting of random distributions, grid-like distribution, one-dimensional grid, equally spaced dots and combinations thereof.

The patterned discontinuous conductive layer 140 can cover a wide range of percentages of the photoabsorber layer 120. In detailed embodiments, the patterned discontinuous conductive layer 140 covers up to about 10% of the photoabsorber layer 120. In various embodiments, the patterned discontinuous conductive layer 140 covers up to about 1%, 2%, 3%, 4%, 5%, 6%, 7%, 8%, 9%, 10%, 11%, 12%, 13%, 14% or 15% of the photoabsorber layer 120. In some embodiments, the patterned discontinuous conductive layer 140 covers in the range of about 1% to about 15% of the photoabsorber layer 120, or in the range of about 2% to about 14% of the photoabsorber layer 120, or in the range of about 3% to about 13% of the photoabsorber layer 120, or in the range of about 5% to about 12% of the photoabsorber layer 120, or in the range of about 7% to about 11% of the photoabsorber layer 120.

Reference throughout this specification to “one embodiment,” “certain embodiments,” “one or more embodiments,” “an embodiment,” “one aspect,” “certain aspects,” “one or more embodiments” and “an aspect” means that a particular feature, structure, material, or characteristic described in connection with the embodiment is included in at least one embodiment of the invention. Thus, the appearances of the phrases such as “in one or more embodiments,” “in certain embodiments,” “in one embodiment,” “in an embodiment,” “according to one or more aspects,” “in an aspect,” etc., in various places throughout this specification are not necessarily referring to the same embodiment or aspect of the invention. Furthermore, the particular features, structures, materials, or characteristics may be combined in any suitable manner in one or more embodiments or aspects. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A photovoltaic cell comprising:
a superstrate;
a front contact layer on the superstrate;
a photoabsorber layer on the front contact, the photoabsorber layer comprising one or more of an n-type layer, a p-type layer and an intrinsic layer;
a patterned discontinuous conductive layer on the photoabsorber layer:
a back contact layer in contact with the photoabsorber layer and the patterned discontinuous conductive layer; and
a reflective layer on the back contact layer, the reflective layer adapted to reflect incident light not absorbed by the photoabsorber layer.

2. The photovoltaic cell of claim 1, wherein the patterned discontinuous conductive layer comprises a metal.

3. The photovoltaic cell of claim 1, wherein the patterned discontinuous conductive layer covers up to about 10% of the photoabsorber layer.

4. The photovoltaic cell of claim 2, wherein the metal is selected from the group consisting of silver, copper, aluminum, indium, tin, nickel, molybdenum, chromium, tantalum, titanium and combinations thereof.

5. The photovoltaic cell of claim 2, wherein the patterned discontinuous conductive layer has a pattern selected from the group consisting of random distributions, grid-like distribution, one-dimensional grid, equally spaced dots and combinations thereof.

6. The photovoltaic cell of claim 1, wherein the patterned discontinuous conductive layer extends through the back contact layer and contacts the reflective layer.

7. The photovoltaic cell of claim 1, wherein one or more of the front contact layer and the back contact layer comprises a transparent conductive oxide.

8. The photovoltaic cell of claim 7, wherein the transparent conductive oxide is aluminum doped zinc oxide.

9. The photovoltaic cell of claim 1, wherein the photoabsorber layer comprises silicon.

10. The photovoltaic cell of claim 1, wherein the reflective layer comprises one or more of a paint layer, a polymer layer impregnated with a white pigment, and a metal selected from the group consisting of silver, copper and combinations thereof.

11. A photovoltaic module comprising a plurality of the photovoltaic cells of claim 1 connected in series.

12. A method of manufacturing a photovoltaic cell, comprising:
depositing a front contact layer onto a superstrate;
depositing a photoabsorber layer onto the front contact, the photoabsorber layer adapted to convert light energy into electrical current, the photoabsorber layer including one or more sublayers selected from the group consisting of p-type, n-type and instrinsic sublayers;
depositing a patterned discontinuous conductive layer on the photoabsorber layer;
depositing a back contact layer onto the patterned discontinuous conductive layer; and
depositing a reflective layer on the back contact layer.

13. The method of claim 12, wherein the patterned discontinuous conductive layer covers up to about 10% of the photoabsorber layer.

14. The method of claim 12, wherein the patterned discontinuous conductive layer comprises a metal.

15. The method of claim 14, wherein the metal is selected from the group consisting of silver, copper, aluminum, indium, tin, nickel, molybdenum, chromium, tantalum, titanium and combinations thereof.

16. The method of claim 12, wherein the patterned discontinuous conductive layer has a pattern selected from the group consisting of random distributions, grid-like distribution, one-dimensional grid, equally spaced dots and combinations thereof.

17. The method of claim 12, wherein the patterned discontinuous conductive layer extends through the back contact layer and contacts the reflective layer.

18. The method of claim 12, wherein one or more of the front contact layer and the back contact layer comprises a conductive transparent oxide.

19. The method of claim 12, wherein the reflective layer comprises a metal selected from the group consisting of silver, copper and combinations thereof.

20. The method of claim 12, further comprising laser scribing the front contact layer, the photoabsorber layer and the back contact layer to create a plurality of individual photovoltaic cells connected in series.
